(19) United States
(12) Patent Application Publication
(10) Pub. No.: US 2009/0277492 A1
(43) Pub. Date: Nov. 12, 2009

(54) SOLAR CELL MODULE

(75) Inventors: Yukihiro Yoshimine, Osaka (JP); Shigeyuki Okamoto, Osaka (JP); Yasufumi Tsunomura, Osaka (JP); Kunimoto Ninomiya, Osaka (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi (JP)

(21) Appl. No.: 12/441,730

(22) PCT Filed: Sep. 19, 2007
(86) PCT No.: PCT/JP2007/068199

§ 371 Date: Apr. 27, 2009

(30) Foreign Application Priority Data
Sep. 28, 2006 (JP) 2006-265941

(51) Int. Cl. H01L 31/042

(52) U.S. Cl. 136/244

(57) ABSTRACT

In a solar cell module, a plurality of solar cells are arranged between a front-surface protection member and a back-surface protection member, and electrodes of the plurality of solar cells is electrically connected to each other by a wring member. The solar cell module includes an adhesive layer including a resin 90 and a plurality of conductive particles 80, between the electrodes 10 and the wiring member 70. Each conductive particle 80 has a flattened shape that a maximum thickness D in a plane perpendicular to a solar cell 20 is smaller than a maximum length L in a plane parallel to the solar cell 20. Both ends of each conductive particle 80 in a thickness direction are respectively in contact with one of the electrodes 10 and the wiring member 70.

### TECHNICAL FIELD

The present invention relates to a solar cell module in which a plurality of solar cells are arranged between a front-surface protection member and a back-surface protection member, and in which electrodes of the plurality of solar cells are electrically connected to each other by a wiring member.

### BACKGROUND ART

Conventionally, a solar cell module includes a plurality of solar cells sealed in a sealing member between a front-surface protection member and a back-surface protection member. The solar cells are electrically connected to each other by wiring members made of a conductive material such as copper foil. The front-surface protection member is made of a translucent material such as a glass, a translucent plastic or the like. The back-surface protection member is made of, for example, a polyethylene terephthalate (PET) film. The sealing member is made of a translucent material such as ethylene vinyl acetate (EVA).

In this respect, to manufacture a HIT solar cell module, wiring members are soldered on bus bar electrodes made of a silver paste as shown in FIG. 1. Specifically, flux is applied onto the surface of each bus bar electrode 10 or onto the surface of each wing member 70 that faces a solar cell 20. Thereafter, the wiring member 70 is disposed on the surface of the bus bar electrode 10 and then heated. Incidentally, the wiring member 70 is generally formed of a metallic material, such as copper foil, completely coated with solder in advance. Meanwhile, the type of the silver paste used in the HIT solar cell module includes a resin to be hardened at a high temperature of approximately 200° C. At his time, the wiring member is soldered by alloying a solder portion of the wiring member with the silver paste while removing an oxide layer on the surface of the bus bar electrode 10, and thereby fixed to the bus bar electrode. After the soldering in this manner, the silver paste (bus bar electrode 10), an alloy layer 100, the solder layer and the copper foil (wiring member 70) are stacked in this order on the solar cell 20.

It is considered that the same resin as that in the silver paste 10 exists in the interface between the silver paste 10 and the alloy layer 100. The resin in the interface is influenced by the high temperature during the soldering. As a result, the resin is, for example, thermally decomposed, and thus damaged. Particularly, there is a tendency of the temperature at the time of soldering to be higher as no lead is used in solder. Thus, the damage to the resin in soldering is also increasing. A technique is disclosed for avoiding the thermal degradation of a bus bar electrode accompanying the lead-free soldering practice (see, for example, Japanese Patent Publication No. 2005-217184). The technique specifies the glass transition temperature range of and the amount of a resin included in a silver paste.

Note that, although the structure of the HIT solar cell module has been described so far, the same structure is adopted in a solar cell module of crystalline solar cells, in which a junction is formed by a generally used thermal diffusion method. To be more specific, after soldering, a silver paste (bus bar electrode 10), an alloy layer 100, a solder layer and copper foil (wiring member 70) are stacked in this order on a solar cell 20. Meanwhile, the type of the silver paste used in the solar cell module formed by the thermal diffusion method includes a resin to be hardened at a high temperature of approximately 700° C.

### DISCLOSURE OF THE INVENTION

However, the thermally damaged resin still remains in the interface between each bus bar electrode 10 and the corresponding wiring member 70 in the conventional solar cell module. Moreover, the residue of the flux also remains in the interface between the bus bar electrode 10 and the wiring member 70. These residues increase the series resistance between the bus bar electrode 10 and the wiring member 70, and thus reduce the power output of the solar cell module.

Furthermore, a stress generated during a temperature cycle test or the like is concentrated in the interface between the silver past and the alloy layer due to not only the difference in thermal expansion coefficient between the silver paste and the alloy layer but also the difference in thermal expansion coefficient between the copper foil and the solar cell, which is a silicon wafer. This reduces the module output, and serves as a factor for reducing the reliability of the module.

The present invention has been made in consideration of these problems. An object of the present invention is to provide a solar cell module having a less reduced module output and an improved reliability.

An aspect of the present invention provides a solar cell module in which a plurality of solar cells are arranged between a front-surface protection member and a back-surface protection member, and in which electrodes of the plurality of solar cells are electrically connected to each other by a wiring member. The solar cell module includes an adhesive layer including a resin and a plurality of conductive paricles, and provided between the electrodes and the wiring member. Each of the plurality of conductive particle has a flattened shape that a maximum thickness in a plane perpendicular to the solar cell is smaller than a maximum length in a plane parallel to the solar cell. Both ends of each of the plurality of conductive particles in a thickness direction are respectively in contact with one of the electrodes and the wiring member.

In the solar cell module according to the aspect of the present invention, the resin maintains the adhesion strength between the wiring member and the electrodes, and every electrical connection between the solar cell and the wiring member is provided by the single conductive particle. Thereby, the reduction in the module output can be suppressed, leading to the improvement in the reliability.

Moreover, in the solar cell module according to the aspect of the present invention, the hardness of the each of the plurality of conductive particles is preferably lower than the hardness of any one of the electrodes and the wiring member.

In the solar cell module, both ends of the each of the plurality of conductive parties in the thickness direction can surely be in contact with one of the electrodes and the wing member, respectively.

The present invention can provide a solar cell module which suppresses the reduction in the module output and improves the reliability.

### BRIEF DESCRIPTION OF THE DRAWINGS

FIG. 1 is an eked sectional view of a solar cell according to Conventional example.

FIG. 2 is a sectional view of a solar cell according to a present embodiment.

FIG. 3 is a sectional view of a solar cell module according to the present embodiment.

FIG. 4 is an enlarged sectional view of the solar cell according to the present embodiment.

FIG. 5 is an enlarged sectional view of a solar cell according to Comparative example.

### BEST MODES FOR CARRYING OUT THE INVENTION

Next, embodiments of the present invention will be described with use of the drawings. In the description of the drawings below, the same or similar components are denoted by the same or similar reference symbols. However, it should be noted that the drawings are drawn schematically, and the dimensional ratios and the like among these components differ from the actual ratios. Accordingly, the specific dimension and the like should be determined in consideration of the following description. In addition, it is needless to say that the drawings may also include the components that have different dimensional relations and ratios among one another.

(Solar Cell Module)

A silicon-based solar cell according to a present embodiment includes electrodes 10, 30 on both made of a silver wafer 20 as shown in FIG. 2. The electrodes 10, 30 are made of a silver paste. At least an electrode on the light entering side is a comb-shaped collecting electrode. The electrodes 10, 30 collect carriers generated inside the cell. The solar cell is connected in series to other cells by a wiring member provided by soldering. The solar cell includes a bus bar electrode and a finger electrode as the electrode. Incidentally, the drawing shows an example where both of the electrodes 10, 30 have the comb shape.

In a solar cell module in which a junction is formed by thermal diffusion, a ceramic-type silver paste is generally used as the electrodes, the ceramic-type silver paste being for sintering a paste blended With silver particles, glass frits, and the like at a high temperature of 500 to 700° C. Meanwhile, the silver paste used in a HIT solar cell module as the electrodes includes: a resin solvent to be hardened at a low temperature of 200° C.; and silver paricles dispersed therein. The present invention is applicable to both the thermally diffused solar cell module and the HIT solar cell module.

Next, a solar cell module according to the present embodiment is formed by electrically connecting the electrodes on the surfaces of the cells 20 in series or parallel to each other by wiring members 70 as shown in FIG. 8. A sealing member 50 made of a resin seals the cells 20. Moreover, a front-surface protection member 40 is disposed on the light entering side of the cells 20, whereas a back-surface protection member 60 is disposed on the side opposite to the light entering side. Furthermore, an Al frame may be attached around the solar cell module in order to increase the strength of the solar cell module and to firmly mount the solar battery module on an abutment.

A glass or the like is suitable as the front-surface protection member 40. A film formed of metal foil such as Al being sandwiched by a PET film and the like is used as the back-surface protection member 60. Moreover, EVA, EEA, PVB, silicone, urethane, acrylic, epoxy, or the like is used as the sealing member 50.

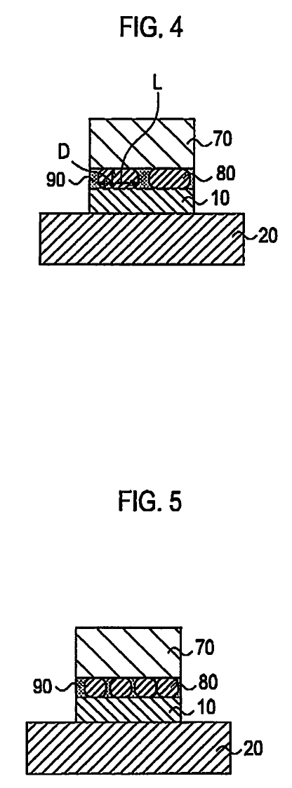

Next, FIG. 4 shows an enlarged sectional view of the interface between the cell 20 and the wiring member 70 in the solar cell module according to the present embodiment.

An adhesive layer is disposed between the electrode 10 and the wiring member 70. The adhesive layer includes a resin 90 and a plurality of conductive particles 80. Each of the conductive particles 80 has a flattened shape that a maximum thickness D in a plane perpendicular to the cell 20 is smaller than a m num length L in a plane parallel to the cell 20. Moreover, both ends of the conductive particle 80 in a thickness direction are respectively in contact with the electrode 10 and the wiring member 70. The hardness of the conductive particle 80 is lower than the hardness of the electrode 10 or the wiring member 70. Here, a Vickers hardness measurement method based on JIB Z 2244 is used as the hardness measurement method.

For example, Al is used as the conductive particle 80. However, any material having a lower hardness than the silver paste of the bus bar electrode or the wiring member can be used. For example, copper, indium, lead, or the like may be used

It should be noted that, in selecting the conductive particle 80, the hardness of the resin 90 at the hardening temperature is particularly important. At the hardening temperature of the resin 90, a conductive material, which has a lower hardness than the electrode and the wiring member, can be used as the conductive particle 80. For example, when tin is used as the conductive particle 80, silver can be used as the electrode material, and copper can be used as the wiring member material. Moreover, when silver is used as the conductive particle 80, copper or tungsten can be used as the electrode or wiring member material. Furthermore, an alloy material or a resin particle such as epoxy, acrylic, polyimide, and a phenol resin, whose spice is coated with a metal film, can be used as the conductive particle 80.

Meanwhile, an example of the resin 90 of the adhesive layer includes an acrylic resin. Besides, the example of the resin 90 is not limited to this, as long as the resin is to have a low internal stress compared with a resin having a high internal stress used in the bus bar electrode. The same effects can be obtained even with use of, for example: resins having a higher molecular weight than the resin used in the bus bar electrode; a resin such as an elastomer having a structural flexibility; resins having a sea-island structure such a mixture of an epoxy resin and a silicone resin; and the like.

(Advantages and Effects)

Conventionally, stress is concentrated on the interface between a silver paste and an alloy layer during a temperature cycle test and other similar occasions due to not only the difference in thermal expansion coefficient between the silver paste and the alloy layer but also the difference in thermal expansion coefficient between a solar cell, which is a silicon wafer, and copper foil used as a wiring member. As a result, the module output is reduced, and the reliability of the module is reduced.

This phenomenon is more apparently shown in a solar cell formed by a thermal diffusion method with use of a ceramic-type silver paste having a high hardness and low flexibility. However, the above phenomenon also appears in a HIT solar cell using a silver paste rich in flexibility. It is assumed that this is caused by the reduced resin flexibility at the thermally degraded resin portion, hindering a sufficient function of relaxing the stress by the thermal expansion between the wiring member and the cell (silicon wafer.

This problem of reduced reliability more apparently appears when the temperature at the time of putting a wiring member is increased along with the lead-free practice, or when the cross-sectional area of the wiring member is increased in order to reduce the resistance loss at the time of building a module. In other words, the conventional soldering method has a problem in reliability on the initial module output, temperature cycle tolerance, and the like.

The above problems can be solved by applying a resin-type paste onto a bus bar electrode, the paste serving as an adhesive layer between the wiring member and the cell, then by disposing the wiring member thereon, and by hardening the adhesive layer to electrically connect the cell to the wiring member. However, the resin-type silver paste used as a collecting electrode of the solar cell needs to be low in resistance. The silver particles in such a silver paste needs to be attracted to ea& other more strongly. Accordingly, the internal stress is increased.

The reason is assumed as follows. Generally, in a resin-type conductive paste, a considerably thin resin layer is interposed among the conductive particles. A tunnel current flows through the resin layer, and electro-conductivity is attained. In order to make the paste low in resistance, the thickness of the resin layer among the silver particles needs to be as thin as possible. For this reason, the internal stress of the low-resistance paste is increased as described above.

When such a paste having a high internal stress is used as an adhesive layer, the internal stress of the paste itself is farter increased due to the increased cross-sectional area of the bus bar electrode. Consequently, the adhesion force between the cell and the silver paste may be reduced in some cases. Such reduction in the adhesion force between the bus bar electrode and the cell may cause, or example, the separation of the wiring member after the wiring member is soldered. Thus, it is desirable not to use a paste having a high internal stress. For this reason, the resin in the paste used as the adhesive layer needs to have a low internal resistance. In this case, the specific resistance is increased in contrast to the above case, and accordingly an additional resistance is formed between the cell and the wiring member.

For the above reasons, a resin-type paste having a low internal stress is desirably used as the adhesive layer between the bus bar and the wiring member. In addition, every electrical path between the bus bar and the wiring member is provided by the single conductive particle in order to avoid the increase in an additional resistance. Furthermore, the contact area between the bus bar and the conductive particles and the contact area between the conductive particles and the wiring member need to be increased as large as possible in order to reduce the resistance between the bus bar and the wiring member in the above case.

In the solar cell module according to the present embodiment, the bus bar electrode is not connected to the wiring member by soldering, and thus it is possible to suppress the initial output reduction of the module due to the influence of the flux residue or the like. Moreover, the stress concentration and fatigue in the alloy layer can be relaxed, improving the temperature cycle tolerance over an extended period. Specifically, the resin having a low internal stress maintains the adhesion strength between the wiring member and the cell, and every electrical connection between the cell and the wiring member is provided by the single conductive particle. Accordingly, the reduction in the module output can be suppressed, and the reliability is improved. Furthermore, each of the conductive particles has a flattened shape as if the conductive particle is crushed from both surfaces thereof. In other words, the thickness in a plane perpendicular to the cell is smaller than the maximum length in a plane parallel to the cell, and the conductive particle is in contact with the cell and the wiring member at both surfaces thereof, respectively, thereby allowing electrical conductivity. Thus, the area contributing the electro-conductivity between the two is increased, and a module having a high power output is obtained.

Moreover, the wiring member and the cell are bonded to each other with the resin surrounding the conductive particles, and thereby firmer adhesion is achieved.

Furthermore, the hardness of the conductive particle is lower than the hardness of the electrode or the wiring member. Thereby, both ends of the conductive particle in the thickness direction can surely be in contact with the electrode and the wiring member, respectively.

(Other Embodiments)

Although the present invention has been described on the basis of the aforementioned embodiment, it should not be understood that the descriptions and drawings that constitute parts of this disclosure limit the present invention. Various alternative embodiments, examples and operation technologies will be apparent to those skilled in the art from this disclosure.

For example, although the description has been given that the collecting electrode is the silver paste in the above-described embodiment, the main component of the collecting electrode is not limited to this.

Thereby, it is needless to say that the present invention includes various embodiments and so forth that are not described herein. Therefore, the technical scope of the present invention is defined only by claimed elements according to the scope of claims as appropriate according to the descriptions above.

### EXAMPLES

Hereinafter, a thin-film solar cell module acceding to the present invention will be specifically described with reference to Example. However, the present invention is not limited to Example illustrated below, and thus can be carried out appropriately while being modified without departing from the gist thereof.

### Example

As a solar cell according to Example of the present invention, a solar cell shown in FIG. 4 was manufactured as follows. The solar call according to Example is a HIT solar cell

Firstly, a resin made of an epoxy resin, an urethane resin, and the like was mixed with silver particles of approximately 1-μmφ spherical powders and approximately 10-μmφ flake powders at a ratio of 20:80 to 10:90 wt % to thereby prepare a paste whose viscosity was adjusted with an organic solvent in an amount of approximately 0.5 to 5% relative to the entire content. This paste was patterned into a comb-shape on a solar cell 20 by a screen-printing method. The paste is hardened in conditions of 200° C. for 1 hour, and a collecting electrode including bus bar electrodes 10 was formed.

Then, a resin made of an acrylic resin and the like serving as an adhesive layer was mixed with approximately 20-μmφ spherical aluminum particles at a ratio of 95:5 to 80:20 wt % to thereby prepare a paste whose viscosity was adjusted with an organic solvent in an amount of approximately 0.5 to 5% relative to the entire content. The resin component in the blending ratio of the paste for the adhesive layer was considerably large in comparison with that of the paste for the collecting electrode. This is because the paste serves as a resin layer to relax the stress between the wiring member and the cell. This paste was applied onto the bus bar electrodes 10, and a wing member 70 was disposed thereon. Subsequently, a pressure of 2 MPa was applied. Thereafter, thermal treatment was conducted at 150° C. for 30 minutes, and the acrylic resin was hardened.

Aluminum is softer than silver, solder, and the like, and accordingly deformed into a flattened shape by the above pressure. Thereby, the thickness in a plane perpendicular to the cell is made smaller than the maximum length in a plane parallel to the cell. The cross section of a sample obtained in Example was observed by SEM. The shape of 20-μm aluminum sphere was observed. The aluminum sphere was deformed to be approximately 30 μm in a direction parallel to the cell and approximately 18 μm in a direction perpendicular to the cell. In this manner, the thickness in the plane perpendicular to the cell was confirmed to be smaller than the maximum length in the plane parallel to the cell. However, the bus bar electrode 10 had an uneven upper surface due to the mesh marks, and the height of the unevenness was at most approximately 5 μm. In such a case, the conductive paricles are deformed along the unevenness, and thus the average thickness should be measured as the thickness.

In this way, using the cell pasted with the wiring member 70, a glass, EVA, the cell, EVA, and a back-surface protection member are stacked in this sequence. After that, thermal treatment was conducted under vacuum at 150° C. for 5 minutes to soften the EVA resin. Then, compression bonding was conducted with heat under atmospheric pressure for 5 minutes, and the solar cell was molded with the EVA resin. Subsequently, the soar cell molded with the EVA resin was held in a high-temperature tank of 150° C. for 50 minutes to crosslink the EVA resin. Thus, a solar cell module was manufactured.

### Comparative Example

A solar cell shown in FIG. 5 was manufactured as a solar cell according to Comparative example. The solar cell according to Comparative example was manufactured by the same manufacturing method as that for the solar cell according to Example except that no pressure was applied after a bus bar electrode 10 was pasted on a wiring member 70, and then an acrylic resin was hardened. Since no pressure was applied, the conductive particles in Comparative example remained spherical.

### Conventional Example

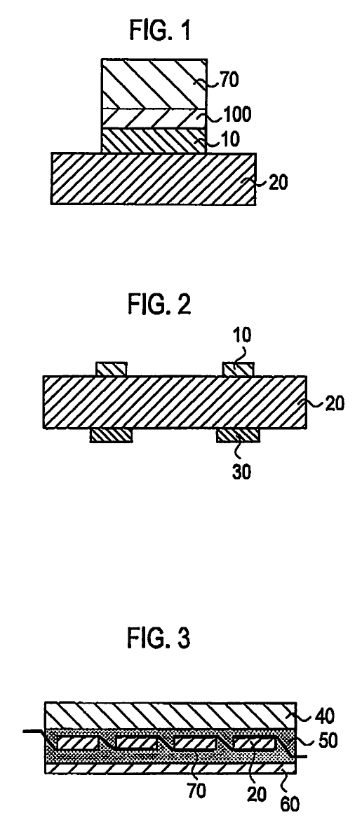

A solar cell shown in FIG. 1 was manufactured as a solar cell according to Conventional example. In the solar cell according to Conventional example, a wiring member 70 was connected to a bus bar electrode 10 by soldering. In the soldering, an organic acid flux was applied on the wiring member 70 on a side of a call 20, and then dried. Thereafter, the wiring member 70 was disposed on the bus bar electrode 10. Subsequently, the cell 20 and the wiring member 70 were blown with a warm air of approximately 300° C. The solder of the wiring member 70 was alloyed with a silver paste of the bus bar electrode 10. Thereby, an alloy layer 100 was formed.

(Evaluation)

The power output coreation was evaluated by comparing the module output after the wiring member was pasted with the module output before the wiring member was pasted (immediately after the collecting electrode was formed) for each of the sir cell modules according to Example, Comparative example, and Conventional example.

Additionally, a temperature cycle test was conducted in accordance with JIS C 8917 on the solar call modules according to Example, Comparative example, and Conventional example. The JIS test specifies a cycle of −40° C. to 90° C. to be repeated 200 cycles. Nevertheless, the test was conducted by increasing the number of cycles up to 400 in order to evaluate a longer-period reliability.

Results)

Table 1 shows the results of the aforementioned cell/module output correlation and temperature cycle test.

TABLE 1

| cell/module | |
|---|---|
| output | heat cycle test |

| | correlation | 200 cycles | 400 cycles |
|---|---|---|---|
| Example | 99% | 98.5% | 98.0% |
| Comparative | 97% | 98.5% | 98.0% |
| example | | | |
| Conventional | 98.5% | 98.0% | 95.5% |
| example | | | |

Here, the value of cell/module output correlation focuses on FF that is a parameter dependent on a resistance component before and after the module was built, and indicates a value of (FF after the module was built)(FF of the cell immediately after the collecting electrode was formed). Meanwhile, (Pmax after the test)/(Pmax value before the test) is shown as the result of the temperature cycle test.

As shown in Table 1, the result shows that the cell/module output correlation is increased in the sequence of Example>Conventional example>Comparative example. The reason is considered as follows. In Conventional example, the flux residue and the alloy layer between the bus bar electrode and the wiring member worked as the resistance component. Meanwhile, in Comparative example, the conductive particles remained spherical, and the electrical connection was achieved in a form of point. As a result, the resistance between the bus bar electrode and the wiring member was increased. In Example, the conductive particles were deformed into the flattened shape by the pressure. Thus, the contact area was increased, and the contact resistance was reduced.

Meanwhile, the result of the temperature cycle test (200 cycles) shows that Example and Comparative example were equivalent to each other, and that Conventional example had a slightly lower value than those of Example and Comparative example. In the 400 cycles, the difference is further widened. In other words, the difference between Example/Comparative example and Conventional example is increased from 0.5% to 2.5%. The reason is considered because of the stress generated due to the difference in thermal expansion coefficient between the wiring member and the cell (silicon wafer). Specifically, the way the stress influences the adhesive layer having a low internal stress that can be relaxed differs from the way the stress influences the alloy layer that cannot be relaxed.

Therefore, it was found out that solar cell module according to Example can achieve both the cell/module output correlation and the longer-period tolerance in the temperature cycle test.

### Other Examples

Although Example has been described regarding the HIT solar cell so far, the same conclusion can be drawn on a crystalline cell formed by a thermal diffusion method. To be more specific, the temperature cycle tolerance greatly differs between: a case where an adhesive layer whose stress can be relaxed is provided between a cell (bus bar electrode) and a wiring member; and a case where an alloy layer whose stress cannot be relaxed is provided therebetween. Furthermore, in the HIT solar cell, although the resin-type silver paste used as the collecting electrode has a relatively high internal stress, the internal stress is low compared with a silver paste sintered as ceramics. Thus, the HIT solar cell is superior in temperature cycle tolerance to the solar cell manufactured by the thermal diffusion method.

Note that die entire content of Japanese Patent Application No. 2006-265941 (filed in Sep. 28, 2006) is incorporated herein by reference.

### INDUSTRIAL APPLICABILITY

As has been described, a solar cell module according to the present invention can achieve an improved reliability by suppressing the reduction of the module output, and thus is useful in photovoltaic power generation.

1. A solar cell module in which a plurality of solar cells are arranged between a front-sure protection member and a back-surface protection member, and in which electrodes of the plurality of solar cells are electrically connected to each other by a wiring member, the solar cell module comprising:
an adhesive layer including a resin and a plurality of conductive particles, and provided between each of the electrodes and the wiring member, wherein
each of the plurality of conductive particles has a flattened shape that a maximum thickness in a plane perpendicular to the solar cell is smaller than a maximum length in a plane parallel to the solar cell, and
both ends of each of the plurality of conductive particles in a thickness direction are respectively in contact with one of the electrodes and the wiring member.

2. The solar cell module according to claim 1 wherein
hardness of each of the plurality of conductive particles is lower than hardness of any one of the electrodes and the wiring member.
